(19) United States
(12) Patent Application Publication
(10) Pub. No.: US 2022/0123161 A1
(43) Pub. Date: Apr. 21, 2022

(54) CASCADED TYPE II SUPERLATTICE INFRARED DETECTOR OPERATING AT 300 K

(71) Applicants: UNIVERSITY OF IOWA RESEARCH FOUNDATION, Iowa City, IA (US); FIREFLY PHOTONICS, LLC, Coralville, IA (US)

(72) Inventors: John Prineas, Iowa City, IA (US); Alexander Walhof, Coralville, IA (US)

(21) Appl. No.: 17/507,752

(22) Filed: Oct. 21, 2021

Related U.S. Application Data
(60) Provisional application No. 63/094,807, filed on Oct. 21, 2020.

(51) Int. Cl. H01L 31/0352; H01L 31/109; H04N 5/33; G01J 5/10

(52) U.S. Cl. CPC H01L 31/035236; H01L 31/109; H01L 31/03046; G01J 5/10; H04N 5/33

(57) ABSTRACT

An apparatus and method for detection of infrared radiation is disclosed. The apparatus includes a detector including a cascaded type II superlattice for detecting infrared radiation. The method includes detecting an infrared radiation signal using a detector that includes n cascading layers comprised of n−1 repeats of a first type II superlattice structure and a tunnel junction, followed by a final (n^{th}) type II superlattice structure, where n is a whole and positive number.

### CROSS-REFERENCE TO RELATED APPLICATIONS

This application claims priority to U.S. Provisional Application No. 63/094,807 that was filed on Oct. 21, 2020. The entire content of the application referenced above is hereby incorporated by referenced herein.

### FIELD

The present disclosure describes a radiation detector.

### BACKGROUND

The present disclosure relates to an apparatus and method for use in detecting infrared radiation. Infrared radiation detectors often require an additional cooling apparatus. This additional cooling apparatus increases the weight, size, and input power of the detector system which makes them unsuitable for many applications. Aspects of the disclosed embodiments address these and other disadvantages and concerns associated with detecting infrared radiation.

### SUMMARY

Consistent with the disclosed embodiments, a method for detecting an infrared radiation signal using a detector that includes n cascading layers comprised of n−1 repeats of a first type II superlattice structure and a tunnel junction, followed by a final (n^{th}) type II superlattice structure, where n is a whole and positive number is disclosed. In some embodiments, the method further includes operating the detector in an uncooled environment. In some embodiments, operating the detector in the uncooled environment comprises operating the detector where the uncooled environment has an ambient temperature of less than about 300 Kelvin. In some embodiments, the infrared radiation signal has a wavelength of between about three microns and about thirty microns. In some embodiments, the infrared radiation signal has a wavelength of between about three microns and about five microns. In some embodiments, the infrared radiation signal has a wavelength of between about eight microns and about twelve microns. In some embodiments, the detector has a specific detectivity of greater than about 1×10⁹ Jones. In some embodiments, the first type II superlattice structure comprises AlGaInSb/InAs and the final type II superlattice structure comprises AlGaInSb/InAs. In some embodiments, the first type II superlattice structure comprises InAs/GaSb and the final type II superlattice structure comprises InAs/GaSb. In some embodiments, the first type II superlattice structure comprises InAs/InAsSb and the final type II superlattice structure comprises InAs/InAsSb. In some embodiments, the first type II superlattice structure comprises a W-Type type II superlattice. In some embodiments, the W-Type type II superlattice comprises AlSb/InAs/InGaSb/InAs. In some embodiments, the first type II superlattice structure includes one or more layers including a group III-V compound semiconductor. In some embodiments, the n-side of the tunnel junction is AlInAsSb, GaInAsSb, InAs, graded superlattice, or other III-V semiconductor. In some embodiments, the p-side of the tunnel junction is GaSb, AlGaSb, or other III-V semiconductor.

Consistent with the disclosed embodiments, an apparatus comprising a detector including a cascaded type II superlattice for detecting infrared radiation is disclosed. In some embodiments, the cascaded type II superlattice including a first type II superlattice structure including AlGaInSb/InAs and a final type II superlattice structure including AlGaInSb/InAs. In some embodiments, the cascaded type II superlattice includes a first type II superlattice structure including AlGaInSb/InAs and a final type II superlattice structure including AlGaInSb/InAs. In some embodiments, the first type II superlattice structure comprises InAs/GaSb and the final type II superlattice structure comprises InAs/GaSb. In some embodiments, the first type II superlattice structure comprises InAs/InAsSb and the final type II superlattice structure comprises InAs/InAsSb. In some embodiments, the cascaded type II superlattice includes a W-Type type II superlattice. In some embodiments, the W-Type type II superlattice comprises AlSb/InAs/InGaSb/InAs. In some embodiments, the cascaded type II superlattice includes one or more layers including a group III element and one or more layers including a group IV element. In some embodiments, the detector has a size of about 100 microns by 100 microns and R₀A of greater than 1.5 Ω-cm². In some embodiments, the detector has a size of between about 30 microns by 30 microns and 100 microns by 100 microns and R₀A of greater than about 1.0. In some embodiments, the detector has a size of less than about 30 microns by 30 microns and R₀A of greater than about 0.5 Ω-cm². In some embodiments, the detector has a size of between about 0.5 square millimeters and about 3.5 square millimeters. In some embodiments, the detector has a size of between about eight microns by eight microns and about three millimeters by three millimeters. In some embodiments, the detector has a size of between about 144 square microns and about four square millimeters. In some embodiments, the detector is included in a detector array. In some embodiments, the detector array is a 1024 by 1024 detector array. In some embodiments, the detector is uncooled. In some embodiments, the detector has a zero dynamic resistance of greater than about 2.0 Ω-cm². In some embodiments, the detector has a specific detectivity of greater than about 1×10⁹ Jones. In some embodiments, the cascaded type II superlattice includes an n-layer and a tunnel junction. In some embodiments, the apparatus further comprises a cooling apparatus thermally coupled to the detector.

Consistent with the disclosed embodiments, a method is disclosed. The method comprises providing an infrared radiation source to emit a source infrared radiation signal. The method comprises receiving the source infrared radiation signal at a gas source and the gas source to generate a transmitted infrared radiation signal. The method comprises detecting the transmitted infrared radiation signal using a radiation detector including a cascaded type II superlattice. In some embodiments, the cascaded type II superlattice comprises an InAs/GaSb type II superlattice. In some embodiments, the cascaded type II superlattice comprises an AlGaInSb/InAs cascaded type II superlattice. In some embodiments, the cascaded type II superlattice comprises an InAs/InAsSb cascaded type II superlattice. In some embodiments, the cascaded type II superlattice comprises a cascaded W-Type type II superlattice. In some embodiments, the W-Type type II superlattice comprises AlSb/InAs/InGaSb/InAs.

Consistent with the disclosed embodiments, a method is disclosed. The method comprises detecting a thermal image at an array of two or more electromagnetic radiation detectors, each of the two or more electromagnetic radiation detectors including a cascaded type II superlattice. In some embodiments, the method further comprises mounting the array of two or more electromagnetic radiation detectors on an aerial vehicle. In some embodiments, the method further comprises mounting the array of two or more electromagnetic radiation detectors on a helmet. In some embodiments, the method further comprises mounting the array of two or more electromagnetic radiation detectors on a vehicle. In some embodiments, the method further comprises mounting the array of two or more electromagnetic radiation detectors on a sea vessel. In some embodiments, the thermal image includes missile or jet exhaust.

### BRIEF DESCRIPTION OF THE DRAWINGS

FIG. 1 shows an apparatus including a detector including a cascaded type II superlattice for detecting infrared radiation in accordance with some embodiments of the present disclosure;

FIG. 2 shows a graph of inverse zero-bias resistance-area product (R₀A) versus perimeter-to-area product for two different type II superlattices in accordance with some embodiments of the present disclosure;

FIG. 3 shows a graph of dynamic resistance of a four-layer type II superlattice and a graph of inverse R₀A versus perimeter-to-area ratio in accordance with some embodiments of the present disclosure;

FIG. 4 shows a graph of an I-V characteristic of a sixteen-stage four-layer type II superlattice in accordance with some embodiments of the present disclosure;

FIG. 5 shows an estimate of responsivity of a sixteen-stage InAs/GaSb type II superlattice in accordance with some embodiments of the present disclosure;

FIG. 6 shows a graph of specific detectivity (D*) of a sixteen-stage InAs/GaSb type II superlattice and a graph of an estimate of leakage current for a sixteen-stage InAs/GaSb type II superlattice in accordance with some embodiments of the present disclosure; and

FIG. 7 shows an illustration of a generic stack for a apparatus including a type II superlattice in accordance with some embodiments of the present disclosure.

### DESCRIPTION

Reference will now be made in detail to the embodiments implemented according to this disclosure, the examples of which are illustrated in the accompanying drawings.

Disclosed is a method of detecting infrared radiation at room temperature (detector is uncooled) using a cascaded type II superlattice photodiode(s). The disclosed apparatus is suitable for use as a single element detector in commercial IR gas sensors and in an array format as an IR focal plane array (FPA) with applications in the defense industry for missile detection and chemical threat detection or in commercial industries as a thermal camera or for detection of chemicals, such as in the detection of chemicals in precision agriculture, or leak detection in pipelines.

Reduction in cost, size, weight, and power (C-SWaP) is critical for wide-spread use of IR FPAs, especially in unmanned aerial vehicles (UAVs) and satellites. Due to its high specific detectivity (>1×10⁹ Jones), the disclosed IR FPA can be used at room temperature (300 Kelvin (K), instead of 77 K to 150 K and eliminates the need to cool the detectors. This will provide a reduction in C-SWaP by removing the cooling system. Further bandgap engineering can increase the uncooled detectivity further. A small, efficient electric cooler may be used when the environment is above 300 K.

The disclosed method of use of the uncooled detector has an unexpected specific detectivity. Also disclosed is the use of the InAs/GaSb type II superlattice design for use as a detector. This use includes an unexpected result that at low or no injection current or incident radiation the type II superlattice is absorptive, acting as a detector, but at high current density becomes transparent or even becomes a gain medium in certain cases which is suitable for an LED/laser.

In this disclosure, a high detectivity mid-infrared detector is achieved with high dynamic resistance. High dynamic impedance is important to achieve a stable, low noise (transimpedance) amplification circuit to effectively read in the response of the detector. Achieving high dynamic resistance has been a challenging problem in mid-wave and longer-wave materials, particularly at higher temperatures. The high dynamic resistance is achieved through cascading the absorbing regions, which results in an N times enhanced dynamic resistance compared to a non-cascaded detector, where N is the number of stages in the device. This comes at the cost of an N times decrease in responsivity, as one electron-hole pair must be created in every absorber region to create a single collected electron-hole pair. Thus, increasing the number of stages doesn't tend to change the overall specific detectivity or D* of the detector, which depends on responsivity and inversely on the square root of resistance; rather, it trades decreased responsivity for increased dynamic resistance. So, in some embodiments, the apparatus uses cascading type II superlattices to achieve high dynamic resistance while maintaining high specific detectivity; high dynamic resistance is important for stable, low noise read-in circuit response. The high dynamic resistance is higher at zero bias, but also much less sensitive to the application of small biases, which further improves stability of the read-in circuit.

Compared to a single stage pn, pin, nBn, or pBp structure, the disclosed structures have N-times enhance dynamic resistance at zero bias while maintaining high specific detectivity, and the dynamic resistance is much less sensitive to small applied biases than a single stage device. These advantages are particularly pronounced at room temperature. N here is the number of cascaded stages. This characteristic enables stable, low noise read-in circuits. Compared to an interband cascaded quantum well detector, the disclosed detector has type II superlattices rather than quantum wells, which enables high absorption and responsivity. Additionally, the disclosed type II superlattice/tunnel junction design has much higher demonstrated dynamic resistance than cascaded interband quantum well detectors. Compared to a cavity detector, which can achieve very high detectivity, responsivity spectrum of the disclosed structures is broader; cavity detectors have very narrow bandwidth.

Additionally, other type II superlattices have been tested, and it was found that a W-Type type II superlattices design has an unexpected 3× higher dynamic resistance than the InAs/GaSb SL, which leads to an unexpected 60% increase in specific detectivity for the same responsivity. Further, the use of a W-Type type II superlattice design to achieve both higher dynamic resistance and higher specific detectivity was also unexpected.

The disclosed W-Type type II superlattice gives the best dynamic resistance. The detector utilizing the disclosed W-Type type II superlattice does much better than previously reported single stage W-Type type II superlattices. That is because single stage W-Type type II superlattices need a single thick absorber to achieve optimal absorption, but that leads to poor responsivity due to poor carrier transport in W-Type type II superlattices. That problem is solved in the disclosed cascaded structure, because the absorber region is broken up into N cascaded regions, so carriers never have to travel very far to be collected (at a tunnel junction).

Further, the use of an n-type cathode is disclosed. The n-type cathode allows the use of a single metal contact recipe for both anode and cathode; reduces parasitic absorption from p-type doping of layers; and may aid in suppression of dark current, and increase of the dynamic resistance. An n-type cathode also reduces parasitic free carrier absorption (compared to a p-type contact layer). Use of the disclosed n-cathode also decreases fabrication steps. The n-type cathode is used for current collection. The n-type cathode is cited in U.S. Pat. No. 10,879,420; but there it is used for current injection and hence called an n-type anode. Here, the n-cathode is used for current collection, a new use.

In some embodiments, forming the detector includes the following:

(1) A type II superlattice structure is grown by molecular beam epitaxy, and is lattice matched to the GaSb substrate in a cascaded system with contact layers, tunnel junctions, and type II superlattice active regions as described in U.S. Pat. No. 10,879,420. The entire content of U.S. Pat. No. 10,879,420 is hereby incorporated by referenced herein.

(2) The wafer is then processed into devices using various lithographic semiconductor processing steps including mesa etching, metallization, passivation and/or encapsulation.

(3) Devices are cleaved or diced from the wafer and hybridized to a read out integrated circuit (ROIC).

Once integrated into read out circuitry the disclosed detector can be used as a single element for detection of IR radiation in a gas sensor or in an array format as a focal plane array in a thermal camera. In the latter approach, it is integrated into a more complex unit including drive electronics and various optical elements to control field of view, focal length, and other optical properties. The array application is suitable for use in defense applications, such as rocket, jet, or missile plume detection.

Working prototype detectors have been fabricated in a commercially compatible 0402 surface mount device packaging that detect from 1.8 um to 4.5 um.

Enablement of some embodiments of the disclosed apparatus is provided in the disclosure of attached U.S. patent application Ser. No. 16/504,493 on cascaded type II superlattices used as light emitting diodes.

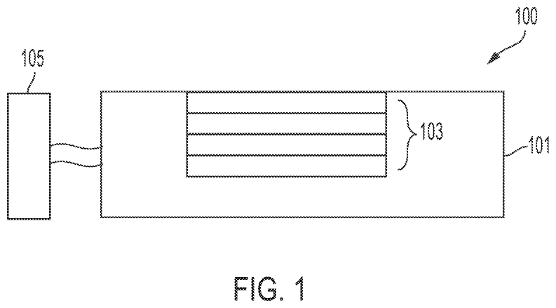

FIG. 1 shows an apparatus 100 including a detector 101 including a cascaded type II superlattice 103 for detecting infrared radiation in accordance with some embodiments of the present disclosure. The detector is not limited to a particular cascaded type II superlattice 103. In some embodiments, the cascaded type II superlattice 103 includes AlGaInSb/GaSb. In some embodiments, the cascaded type II superlattice 103 includes InAs/GaSb. In some embodiments, the cascaded type II superlattice 103 includes InAs/InAsSb. In some embodiments, the cascaded type II superlattice 103 include a W-Type type II superlattice. A W-Type type II superlattice is a type of symmetric type II superlattice that introduces a barrier layer to the type II superlattice stack to balance strain and enhance spatial wavefunction overlap where the higher energy offset semiconductor is repeated on either side of the lower energy offset semiconductor. In some embodiments, the W-Type type II superlattice includes AlSb/InAs/InGaSb/InAs.

The detector 101 is not limited to a particular size. In some embodiments, the detector 101 has a size of about 100 microns by 100 microns and R₀A of greater than 1.5 Ω-cm². In some embodiments, the detector 101 has a size of between about 30 microns by 30 microns and 100 microns by 100 microns and R₀A of greater than about 1.0 Ω-cm². In some embodiments, the detector 101 has a size of less than about 30 microns by 30 microns and R₀A of greater than about 0.Ω-cm².

In some embodiments, the detector 101 has a size of between about 0.5 square millimeters and about 3.5 square millimeters. In some embodiments, the detector 101 has a size of between about eight microns by eight microns and about three millimeters by three millimeters. In some embodiments, the detector 101 has a size of between about 144 square microns and about four square millimeters. In some embodiments, the detector 101 is included in a detector array. In some embodiments, the detector array is a 1024 by 1024 detector array.

In some embodiments, the detector 101 is uncooled. The detector 101 is uncooled when there is no auxiliary device to alter the ambient temperature or the temperature of the detector 101. In some embodiments, the detector 101 has a zero bias dynamic resistance of greater than about 2.0 Ω-cm². In some embodiments, the detector 101 has a specific detectivity of greater than about 1×10⁹ Jones.

In some embodiments, the cascaded type II superlattice 103 includes n-layer and a tunnel junction. In some embodiments, the apparatus 100 further includes a cooling apparatus 105 thermally coupled to the detector 101.

In some embodiments, the cascaded type II superlattice 103 includes a first type II superlattice structure including AlGaInSb/InAs and a final type II superlattice structure including AlGaInSb/InAs. In some embodiments, the cascaded type II superlattice 103 includes a first type II superlattice structure including InAs/GaSb and a final type II superlattice structure including InAs/GaSb.

In some embodiments, a method includes detecting an infrared radiation signal using a detector that includes n cascading layers comprised of n−1 repeats of a first type II superlattice structure and a tunnel junction, followed by a final (n^{th}) type II superlattice structure, where n is a whole and positive number. In some embodiments, the method further includes operating the detector in an uncooled environment. An uncooled environment is an environment that does not include a cooling element or structure or device to change the temperature of the detector directly or the environment near the detector. In some embodiments, operating the detector in the uncooled environment includes operating the detector where the uncooled environment has an ambient temperature of less than about 300 K. In some embodiments, the first type II superlattice structure includes one or more layers including a group III-V compound semiconductor.

The infrared radiation signal is not limited to a particular wavelength. In some embodiments, the infrared radiation signal has a wavelength of between about three microns and about thirty microns. In some embodiments, the infrared radiation signal has a wavelength of between about three microns and about five microns. In some embodiments, the infrared radiation signal has a wavelength of between about eight microns and about twelve microns. In some embodiments, the detector has a specific detectivity of greater than about 1×10⁹ Jones.

The first type II superlattice and the final type II superlattice are not limited to particular materials or a particular stack of materials. In some embodiments, the first type II superlattice includes AlGaInSb/InAs and the final type II superlattice structure includes AlGaInSb/InAs. In some embodiments, the first type II superlattice includes InAs/GaSb and the final type II superlattice structure includes InAs/GaSb. In some embodiments, the first type II superlattice includes InAs/InAsSb and the final type II superlattice structure includes InAs/GaSb. In some embodiments, the first type II superlattice includes a W-Type type II superlattice and the final type II superlattice structure includes as W-Type type II superlattice. In some embodiments, the W-Type type II superlattice includes AlSb/InAs/InGaSb/InAs.

In some embodiments, a method includes providing an infrared radiation source to emit a source infrared radiation signal, receiving the source infrared radiation signal at a gas source and the gas source to generate a transmitted infrared radiation signal, and detecting the transmitted infrared radiation signal using a radiation detector including a cascaded type II superlattice. The cascaded type II superlattice is not limited to a particular material or a particular stack of materials. In some embodiments the cascaded type II superlattice includes an InAs/GaSb type II superlattice. In some embodiments, the cascaded type II superlattice includes an AlGaInSb/InAs cascaded type II superlattice. In some embodiments, the cascaded type II superlattice includes an InAs/InAsSb cascaded type II superlattice. In some embodiments, the cascaded type II superlattice comprises a cascaded W-Type type II superlattice. In some embodiments, the W-Type type II superlattice includes AlSb/InAs/InGaSb/InAs.

In some embodiments, a method includes detecting a thermal image at an array of two or more electromagnetic radiation detectors. Each of the two or more electromagnetic radiation detectors includes a cascaded type II superlattice. In some embodiments, the method further includes mounting the array of two or more electromagnetic radiation detectors on an aerial vehicle. The aerial vehicles on which the array is mounted is not limited to a particular type of aerial vehicle. Examples of aerial vehicles on which the array can be mounted include rockets, missiles, and unmanned aerial vehicles. In some embodiments, the thermal image includes missile or jet exhaust. In some embodiments, the method further includes mounting the array of two or more electromagnetic radiation detectors on a helmet, such as a protective helmet.

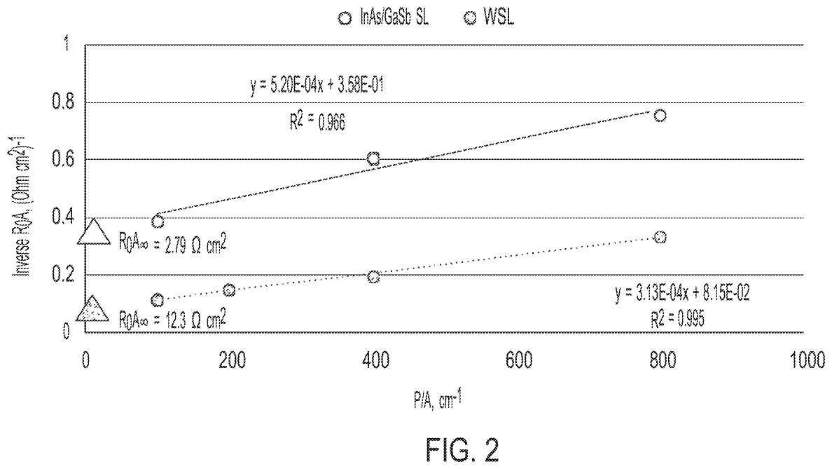

FIG. 2 shows a graph of zero-bias resistance area product (R₀A) versus perimeter-to-area product for two different type II superlattices in accordance with some embodiments of the present disclosure. The graph illustrates the size dependent resistance of a W-structured type II superlattice (WSL) and an InAs/GaSb type II superlattice. Better performance is shown for the W-structured type II superlattice (WSL).

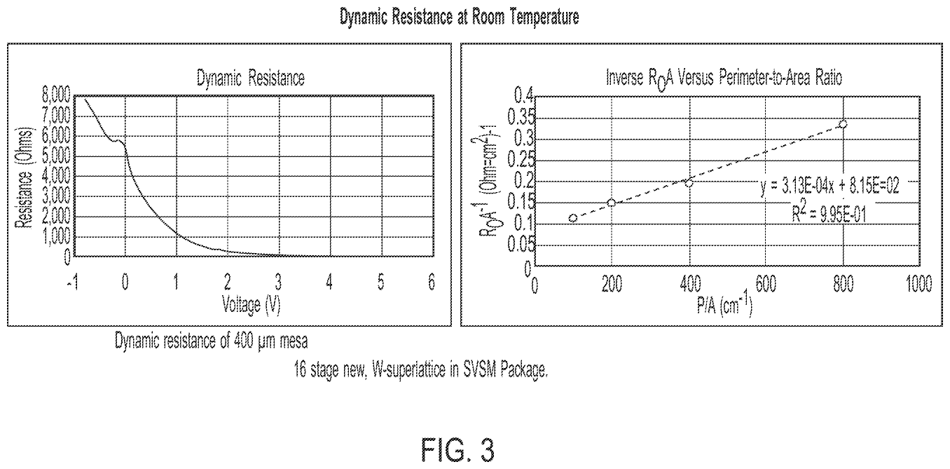

FIG. 3 shows a graph of dynamic resistance of a W-Type type II superlattice device and a graph of inverse R₀A versus perimeter-to-area ratio in accordance with some embodiments of the present disclosure. The dynamic resistance graph shows slowly decreasing resistance with increasing voltage. The inverse R₀A versus perimeter-to-area ratio graph shows increasing inverse R₀A with increasing perimeter-to-area ratio.

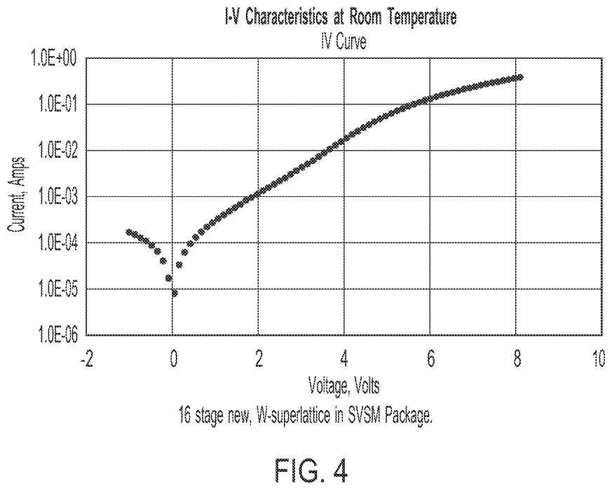

FIG. 4 shows a graph of an I-V characteristic of a sixteen-stage four-layer type II superlattice in accordance with some embodiments of the present disclosure. The graph of the I-V characteristic shows increasing current with increasing voltage.

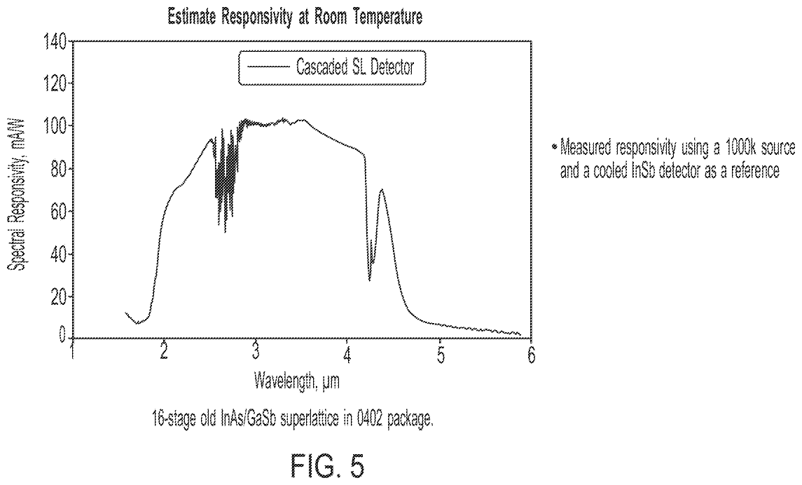

FIG. 5 shows an estimate of responsivity of a sixteen-stage InAs/GaSb type II superlattice in accordance with some embodiments of the present disclosure. FIG. 5 shows a substantially flat response for radiation having a wavelength of between about three microns and four microns.

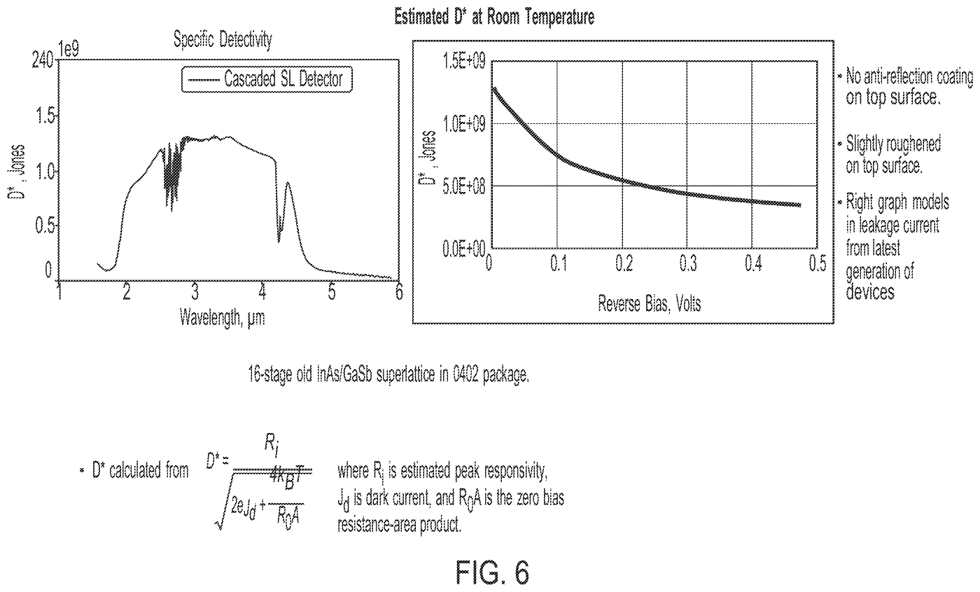

FIG. 6 shows a graph of specific detectivity (D*) of a sixteen-stage InAs/GaSb type II superlattice and a graph of the dependence of D* on reverse bias voltage for a sixteen-stage InAs/GaSb type II superlattice in accordance with some embodiments of the present disclosure. The specific detectivity graph shows a substantially flat response for radiation having a wavelength of between about three microns and about four microns. The graph showing D* versus voltage shows D* decreases is relatively insensitive to reverse bias, in contrast to non-cascaded detectors.

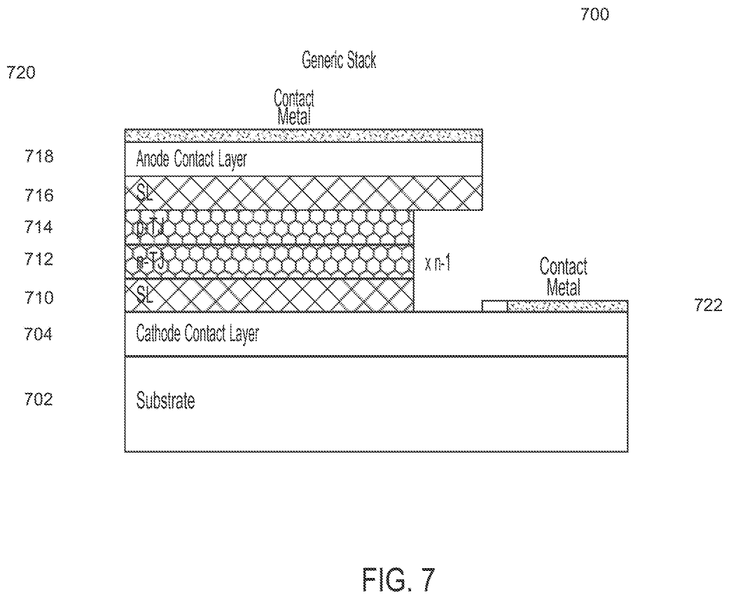

FIG. 7 shows an illustration of a generic stack 700 for an apparatus including a type II superlattice in accordance with some embodiments of the present disclosure. The generic stack 700 includes a substrate 702, a cathode contact layer 704, a SL (type II superlattice) layer 710, an n-TJ (tunnel junction) layer 712, a p-TJ (tunnel junction) layer 714, an SL (type II superlattice) layer 716, an anode contact layer 718, a metal contact 720 in contact with the anode contact layer 718, and a metal contact 722 in contact with the cathode contact layer 704. In some embodiments, the SL (type II superlattice) layer 710, the n-TJ (tunnel junction) layer 712, and the p-TJ (tunnel junction) layer 714 is repeated n-1 times, where n is a positive integer, followed by a SL (type II superlattice) layer 716.

The cathode contact layer 704 in some embodiments includes a p-type layer. In some embodiments, the cathode contact layer 704 includes an n-type cathode realized with three layers, an n-type contact layer followed by an n-type tunnel junction layer and a p-type tunnel junction layer. In some embodiments, the n-type contact layer has a thickness of between about 0.5 microns and about two microns. In some embodiments, the n-type contact layer has a thickness of between about two and about five microns.

The superlattice is separate from the tunnel junction. In operation, the superlattice absorbs radiation while the tunnel junction acts as an electrical gate between absorbing superlattice stages. In operation, the tunnel junction transfers current from one absorbing stage to the next. The tunnel junction is a diode having an n-layer and a p-layer reversed with respect to a detector diode. The p-type tunnel junction layer is not limited to a particular material. The n-type tunnel junction layer is not limited to a particular material.

In some embodiments, the tunnel junction includes an n-side which comprises an n-doped AlInAsSb, GaInAsSb, InAs, a graded type II superlattice, or other compound III-V semiconductor. In some embodiments, the tunnel junction includes a p-side which comprises p-doped GaSb, AlGaSbAs, or other III-V compound semiconductors. In some embodiments, the cathode contact layer is p-type. In some embodiments, the detector includes a cathode contact layer including a an n-doped layer, and a tunnel junction with an n-side and p-side.

The tunnel junction (TJ) layers, such as p-TJ layer 714 and n-TJ layer 712, and are not limited to a particular thickness. In some embodiments, the tunnel junction layers are between about five and thirty nanometers. In some embodiments, the tunnel junction layers are about twenty nanometers. In some embodiments, the thickness of the tunnel junction layers are greater than thirty nanometers. In some embodiments, the thickness of the tunnel junction layers are between about thirty nanometers and about fifty nanometers.

In some embodiments, a superlattice layer, such as superlattice layer 710, has a thickness of about 200 nanometers. In some embodiments, the superlattice layer 710 has a thickness of about 200 nanometers. In some embodiments, the superlattice layer 710 has a thickness of between about 50 nanometers and 300 nanometers. In some embodiments, the superlattice layer 710 has a thickness of greater than about 300 nanometers.

A superlattice is a quasi-2D structure that includes of a repetition of two or more semiconductor layers with an overall bandgap, bandstructure, and band offsets determined by, but different from, the constituent layers. In a type II superlattice, band offsets of the constituent layers are such that the electron is more likely to be found in one layer, known as the electron well, and the hole is more likely to be found in a different layer, known as the hole-well.

In the preceding specification, various example embodiments have been described with reference to the accompanying drawings. It will, however, be evident that various modifications and changes can be made thereto, and additional embodiments may be implemented based on the principles of the present disclosure. The specification and drawings are accordingly to be regarded in an illustrative rather than restrictive sense.

For example, advantageous results still could be achieved if steps of the disclosed techniques were performed in a different order or if components in the disclosed systems were combined in a different manner or replaced or supplemented by other components. Other implementations are also within the scope of the following example claims.

What is claimed is:

1. A method comprising:
detecting an infrared radiation signal using a detector that includes n cascading layers comprised of n−1 repeats of a first type II superlattice structure and a tunnel junction, followed by a final (n^{th}) type II superlattice structure, where n is a whole and positive number.

2. The method of claim 1, further comprising operating the detector in an uncooled environment.

3. The method of claim 2, wherein operating the detector in the uncooled environment comprises operating the detector where the uncooled environment has an ambient temperature of less than about 300 Kelvin.

4. The method of claim 1, wherein the infrared radiation signal has a wavelength of between about three microns and about thirty microns.

5. The method of claim 1, wherein the infrared radiation signal has a wavelength of between about three microns and about five microns.

6. The method of claim 1, wherein the infrared radiation signal has a wavelength of between about eight microns and about twelve microns.

7. The method of claim 1, wherein the detector has a specific detectivity of greater than about 1×10⁹ Jones.

8. The method of claim 1, wherein the first type II superlattice structure comprises AlGaInSb/InAs and the final type II superlattice structure comprises AlGaInSb/InAs.

9. The method of claim 1, wherein the first type II superlattice structure comprises InAs/GaSb and the final type II superlattice structure comprises InAs/GaSb.

10. The method of claim 1, wherein the first type II superlattice structure comprises a W-Type type II superlattice.

11. The method of claim 10, wherein the W-Type type II superlattice comprises AlSb/InAs/InGaSb/InAs.

12. The method of claim 1, wherein the first type II superlattice structure includes one or more layers including a group III-V compound semiconductor.

13. The method of claim 1, wherein the tunnel junction includes an n-side which comprises an n-doped AlInAsSb, GaInAsSb, InAs, a graded type II superlattice, or other compound group III-V semiconductor.

14. The method of claim 1, wherein the tunnel junction includes a p-side which comprises p-doped GaSb, AlGaSbAs, or other group III-V compound semiconductor.

15. The method of claim 1, wherein the cathode contact layer is p-type.

16. The method of claim 1, wherein the detector includes a cathode contact layer including an n-doped layer, and a tunnel junction with an n-side and p-side.

17. An apparatus comprising a detector including a cascaded type II superlattice for detecting infrared radiation.

18. The apparatus of claim 17, wherein the cascaded type II superlattice including a first type II superlattice structure including AlGaInSb/InAs and a final type II superlattice structure including AlGaInSb/InAs.

19. The apparatus of claim 17, wherein the cascaded type II superlattice includes a first type II superlattice structure including AlGaInSb/InAs and a final type II superlattice structure including AlGaInSb/InAs.

20. The apparatus of claim 17, wherein the cascaded type II superlattice includes a W-Type type II superlattice.

21. The apparatus of claim 20, wherein the W-Type type II superlattice comprises AlSb/InAs/InGaSb/InAs.

22. The apparatus of claim 17, wherein the cascaded type II superlattice includes one or more layers including a group III-V compound semiconductor.

23. The apparatus of claim 17, wherein the detector has a size of about 100 microns by 100 microns and R₀A of greater than 1.5 Ω-cm².

24. The apparatus of claim 17, wherein the detector has a size of between about 30 microns by 30 microns and 100 microns by 100 microns and R₀A of greater than about 1.0 Ω-cm².

25. The apparatus of claim 17, wherein the detector has a size of less than about 30 microns by 30 microns and R₀A of greater than about 0.5 Ω-cm².

26. The apparatus of claim 17, wherein the detector has a size of between about 0.5 square millimeters and about 3.5 square millimeters.

27. The apparatus of claim 17, wherein the detector has a size of between about eight microns by eight microns and about three millimeters by three millimeters.

28. The apparatus of claim 17, wherein the detector has a size of between about 144 square microns and about four square millimeters.

29. The apparatus of claim 17, wherein the detector is included in a detector array.

30. The apparatus of claim 29, wherein the detector array is a 1024 by 1024 detector array.

31. The apparatus of claim 17, wherein the detector is uncooled.

32. The apparatus of claim 17, wherein the detector has a specific detectivity of greater than about 1×10⁹ Jones.

33. The apparatus of claim 17, further comprising a cooling apparatus thermally coupled to the detector.

34. A method comprising:
providing an infrared radiation source to emit a source infrared radiation signal;
receiving the source infrared radiation signal at a gas source and the gas source to generate a transmitted infrared radiation signal; and
detecting the transmitted infrared radiation signal using a radiation detector including a cascaded type II superlattice.

35. The method of claim 34, wherein the cascaded type II superlattice comprises an InAs/GaSb type II superlattice.

36. The method of claim 34, wherein the cascaded type II superlattice comprises an AlGaInSb/InAs cascaded type II superlattice.

37. The method of claim 34, wherein the cascaded type II superlattice comprises a cascaded W-Type type II superlattice.

38. The method of claim 37, wherein the W-Type type II superlattice comprises AlSb/InAs/InGaSb/InAs.

39. A method comprising:
detecting a thermal image at an array of two or more electromagnetic radiation detectors, each of the two or more electromagnetic radiation detectors including a cascaded type II superlattice.

40. The method of claim 39, further comprising mounting the array of two or more electromagnetic radiation detectors on an aerial vehicle.

41. The method of claims 39, further comprising mounting the array of two or more electromagnetic radiation detectors on a helmet.

42. The method of claims 39, further comprising mounting the array of two or more electromagnetic radiation detectors on a vehicle.

43. The method of claims 39, further comprising mounting the array of two or more electromagnetic radiation detectors on a sea vessel.

44. The method of claim 39, wherein the thermal image includes missile or jet exhaust.
